(19) United States
(12) Patent Application Publication
(10) Pub. No.: US 2006/0076625 A1
(43) Pub. Date: Apr. 13, 2006

(54) Field effect transistors having a strained silicon channel and methods of fabricating same

(76) Inventors: Sung-young Lee, Gyeonggi-do (KR); Dong-suk Shin, Gyeonggi-do (KR)

Correspondence Address: MYERS BIGEL SIBLEY & SAJOVEC, PO BOX 37428, RALEIGH, NC, 27627, US

(21) Appl. No.: 11/033,769

(22) Filed: Jan. 12, 2005

(30) Foreign Application Priority Data
Sep. 25, 2004 (KR) 2004-77593

(51) Int. Cl. H01L 27/12

(52) U.S. Cl. 257/353

(57) ABSTRACT

Field effect transistors (FETs) and methods of fabricating FETs that include a channel layer on sidewalls of a structure on a semiconductor substrate and having at least a portion of the channel layer strained in a direction that the sidewalls of the structure extend from the semiconductor substrate are provided. The transistor may be a FinFET, the structure on the semiconductor substrate that includes a fin structure and the sidewalls may be sidewalls of the fin structure. The channel layer may be a Si epitaxial layer and may be on an inner fin structure that includes alternating layers of SiGe and Si. The channel layer may include strained and unstrained portions. The strained and unstrained portions may be sidewalls of the channel layer.

### CLAIM OF PRIORITY AND CROSS-REFERENCE TO RELATED APPLICATIONS

This application claims priority from Korean Patent Application No. 2004-77593, filed on Sep. 25, 2004, the contents of which are hereby incorporated herein by reference in its entirety.

### FIELD OF THE INVENTION

The present invention relates to semiconductor devices, and more specifically, to field effect transistors (FETs) and related devices.

### BACKGROUND OF THE INVENTION

Over the past 30 years, developments in silicon-based integrated circuit technology, such as metal-oxide-semiconductor (MOS) devices including field effect transistors (FETs and/or MOSFETs), have provided greater device speed, increased integration density, and improved device functionality with reduced cost. Referring to FIG. 1A, MOS devices are typically formed in a substrate 10 having heavily-doped source/drain (S/D) regions 12 separated by a more lightly-doped channel region 18. The channel region 18 may be controlled by a gate electrode 14 that is separated from the channel region by a gate dielectric 16.

However, with increasing requirements for higher integration as well as higher performance, lower power dissipation, and greater economic efficiency, a variety of problems associated with degradation of transistor characteristics may arise. For example, as the channel length of a transistor is reduced, short-channel effects such as punch-through, drain induced barrier lowering (DIBL), sub-threshold swing, increased parasitic capacitance between a junction region and the substrate (i.e. junction capacitance), and increased leakage current may occur.

A variety of transistor designs have been developed which may address some of the problems faced by conventional bulk-MOS semiconductor devices. These transistor designs have included, for example, ultra-thin body transistors, double gate transistors, recessed channel array transistors (RCATs), FinFETs and gate-all-around transistors (GAATs).

For example, FIG. 1B illustrates a conventional ultra-thin body transistor. In an ultra-thin body transistor, the channel region 18 may be formed in a thin layer above an insulating region. Also, FIG. 1C illustrates a conventional double-gate transistor. In a double gate transistor, a single channel region 18 may be controlled by two gates 14a and 14b that are separated from the channel region by gate dielectrics 16a and 16b. As such, both sides of the channel region may be controlled.

However, the devices of FIGS. 1B and 1C may require more complex fabrication techniques, which may increase cost and decrease yield. Accordingly, such devices may be less practical in general semiconductor manufacturing.

For example, ultra-thin body transistors may be considerably more expensive to produce than conventional bulk-MOS devices. Although they may provide improved performance in some areas, ultra-thin body transistors may be susceptible to floating body and heat transfer effects, and may have current limitations imposed by the body thickness.

In addition, by controlling the channel from two sides, double-gate devices may exhibit improved leakage performance. However, double-gate devices may require a more complex fabrication processes, which may increase expense and lower yield. More particularly, it may be difficult to align upper gate 14a and lower gate 14b (as shown in FIG. 1C) in double-gate transistor fabrication.

Gate-all-around transistors have been described in, for example, U.S. Pat. No. 6,391,782 to Yu entitled “PROCESS FOR FORMING MULTIPLE ACTIVE LINES AND GATE-ALL-AROUND MOSFET.”

FinFET transistors, in which the channel region is formed in a vertically protruding “fin” of semiconductor material, may provide leakage performance similar to or better than that of double-gate transistors, but may be less complicated and less expensive to produce. FinFET transistors (or simply FinFETs) may also support scaling to sub-50 nm channel lengths (and perhaps as low as 10 nm), which may provide additional improvements in integration density and operational speed. FinFET structures are described in U.S. Pat. No. 6,413,802 to Hu et al. entitled “FINFET TRANSISTOR STRUCTURES HAVING A DOUBLE GATE CHANNEL EXTENDING VERTICALLY FROM A SUBSTRATE AND METHODS OF MANUFACTURE.”

In FinFETs, the channel region may be formed in a vertically oriented fin-shaped active region protruding from the semiconductor substrate, as discussed above. The gate dielectrics may be formed on the fin, and the gate electrode may be formed around the fin. The channel region may be formed first, followed by source and drain regions. The source/drain regions may be taller than the fin. Dielectric and conductive materials may then be used to form double- and/or triple-gate devices.

FIGS. 2A to 2D are cross-sectional views of a semiconductor substrate illustrating conventional methods for forming a FinFET.

Referring now to FIG. 2A, an etch mask pattern 13 is formed on a silicon substrate 10. A portion of the silicon substrate 10 exposed by the etch mask pattern 13 is anisotropically etched to form a silicon fin 15. An upper edge of the silicon fin 15 is formed at a sharp angle (i.e. at nearly a right angle) due to the anisotropic etching. The etch mask pattern 13 may be formed of nitride, and a thermal oxide layer may be formed between the nitride and substrate. In order to provide electrical insulation between neighboring silicon fins, a device isolation layer 17 is formed, as shown in FIG. 2B.

Referring now to FIG. 2C, a portion of the device isolation layer 17 is removed, exposing lateral surfaces, or sidewalls, of the silicon fin 15. The lateral surfaces of the silicon fin 15 may serve as a channel region for a transistor.

Referring to FIG. 2D, a gate insulating layer 19 is formed on the exposed sidewalls of the silicon fin 15, and a gate electrode 21 is formed to create a double-gate FinFET. Both sidewalls of the silicon fin 15 may be controlled by the gate electrode 21.

According to conventional methods for forming double-gate FinFETs, adhesion between the etch mask pattern 13 and the substrate 10 may be weakened when a portion of the device isolation layer 17 is removed. Since the device isolation layer 17 may also be formed of an oxide, a thermal oxide layer of the etch mask pattern 13 on a portion of silicon fin may be removed along with the portion of the device isolation layer 17. As the width of the silicon fin 15 may be decreased to allow for higher device integration, it may be increasingly possible for the etch mask pattern 13 to be separated from the upper surface of the silicon fin 15. If the etch mask pattern is removed, an upper surface of the silicon fin 15 may be controlled by the gate electrode 21, and a triple-gate FinFET may be formed. Accordingly, double-gate and triple-gate FinFETs may be formed on the same wafer.

Still referring to FIG. 2D, in order to form higher-performance devices, the width of the silicon fin 15 may be decreased by performing a thermal oxidation process before forming the gate insulating layer 19. In other words, the width of the silicon fin 15 may be reduced by forming a sacrificial oxide layer at sidewalls of the fin 15 using a thermal oxidation process, and then removing the sacrificial oxide layer. As such, the fin 15 may have a width narrower than that of the etch mask pattern 13. Accordingly, an under-cut region may be formed under the etch mask pattern 13, resulting in poor step coverage during subsequent processes, such as the deposition of gate electrode material. In addition, if the sacrificial oxide layer is removed, the thermal oxide layer of the etch mask pattern 13 may also be partially removed. As a result, the etch mask pattern 13 may be separated from the silicon fin 15, and the problems described above may occur.

Triple-gate FinFETs have been developed which may address some of these problems. In triple-gate FinFETs, an upper surface and both sidewalls of the silicon fin are controlled by a gate electrode, which may improve current driving capacity.

A conventional method for forming a triple-gate FinFET will be described with reference to FIGS. 3A to 3B. Triple-gate FinFETs can be formed by removing the etch mask pattern in the conventional methods for forming double-gate FinFETs described above with reference to FIGS. 2A to 2D.

As shown in FIG. 2B, a silicon fin 15 and a device isolation layer 17 are formed. Then, as shown in FIG. 3A, a portion of the device isolation layer 17 and an etch mask pattern 13 are removed. As a result, both sidewalls and an upper surface of the silicon fin 15 are exposed.

Referring to FIG. 3B, a gate insulating layer 19 is formed on the exposed surfaces (i.e., both sidewalls and the upper surface) of the silicon fin 15, and then a gate electrode 21 is formed.

Enhanced mobility transistors using a strained channel have also been explored to improve transistor performance. These transistors have generally used a thick epitaxial SiGe layer as a stress generator or used an epitaxial silicon on germanium on insulator (SGOI) wafer. However, the use of a thick SiGe layer or an SGOI wafer may be expensive to manufacture. Furthermore, the strained-channel transistors have typically been implemented in a planar structure. Strained channel transistors are described in, for example, Hoyt et al., “Strained Silicon MOSFET Technology,” Electron Devices Meeting, 2002. IEDM '02. Digest. International, pp. 23-26; Ota et a., “Novel Locally Strained Channel Technique for High Performance 55 nm CMOS,” Electron Devices Meeting, 2002. IEDM '02. Digest. International, pp. 27-30; Rim et al., “Fabrication and Mobility Characteristics of Ultra-thin Strained Si Directly on Insulator (SSDOI) MOSFETs,” Electron Devices Meeting, 2003. IEDM '03 Technical Digest. IEEE International, pp. 3.1.1-3.1.4; Takagi et al., “Channel Structure Design, Fabrication and Carrier Transport Properties of Strained-Si/SiCe-On-Insulator (Strained SOI) MOSFETs,” Electron Devices Meeting, 2003. IEDM '03 Technical Digest. IEEE International, pp. 3.3.1-3.3.4; Ge et al., “Process-Strained Si (PSS) CMOS Technology Featuring 3D Strain Engineering,” Electron Devices Meeting, 2003. IEDM '03 Technical Digest. IEEE International, pp. 3.7.1-3.7.4; and Ernst et al., “Fabrication of a novel strained SiGe:C-channel planar 55 nm nMOSFET for High-Performance CMOS,” 2002 Symposium on VLSI Technology Digest of Technical Papers, the disclosures of which are incorporated herein by reference as if set forth fully herein.

### SUMMARY OF THE INVENTION

Some embodiments of the present invention provide field effect transistors (FETs) and methods of fabricating FETs that include a channel layer on sidewalls of a structure on a semiconductor substrate and having at least a portion of the channel layer strained in a direction that the sidewalls of the structure extend from the semiconductor substrate.

In particular embodiments of the present invention, the transistor comprises a FinFET, the structure on the semiconductor substrate comprises a fin structure and the sidewalls comprise sidewalls of the fin structure. The channel layer comprises may be a Si epitaxial layer. The channel layer may have a thickness of less than about 100 Å. In particular embodiments of the present invention, the substrate comprises a Si substrate. The channel layer may include strained and unstrained portions. The strained and unstrained portions may comprise sidewalls of the channel layer.

In further embodiments of the present invention, the fin structure includes a plurality of layers of different materials. Each of the plurality of layers of different materials includes an upper surface opposite and substantially parallel to the substrate and a sidewall surface that is substantially perpendicular to the substrate and the channel layer may be directly on the sidewall surfaces of the plurality of layers of different materials.

In some embodiments of the present invention, the fin structure includes alternating layers of Si and SiGe. The alternating layers may be epitaxial layers. The Si layers of the alternating layers may have a thickness of less than about 30 Å. The SiGe layers of the alternating layers may have a thickness of less than about 50 Å. The alternating layers may include more than one layer of Si and more than one layer of SiGe. Furthermore, an outermost layer of the alternating layers may be a SiGe layer. A portion of the channel layer may be disposed directly on the outermost layer of the alternating layers.

In additional embodiments of the present invention, a FinFET includes a gate dielectric on the channel layer, a gate electrode on a portion of the gate dielectric and source and drain regions on opposite sides of the gate electrode. The channel layer may comprise a Si epitaxial layer. The source and drain regions may comprise the Si epitaxial layer. The fin structure and the source and drain regions may comprise a plurality of layers of different materials. The fin structure and the source and drain regions may comprise alternating layers of Si and SiGe. The alternating layers may comprise epitaxial layers. The gate electrode may comprise a poly-silicon layer. In particular embodiments of the present invention, the channel layer includes portions that are strained in a direction parallel to a gate width. Furthermore, the gate dielectric and the gate electrode may comprise a damascene structure.

In still further embodiments of the present invention, a FinFET includes a first dielectric layer on the substrate and the fin structure extends through the first dielectric layer and the channel layer is disposed on a portion of the fin structure extending beyond the first dielectric layer. The fin structure may include a portion of the substrate, where the portion of the fin structure provided by the substrate extends beyond the first dielectric layer. Alternatively, the fin structure may include a portion of the substrate where the portion of the fin structure provided by the substrate does not extend beyond the first dielectric layer.

Some embodiments of the present invention provide Fin field effect transistors (FETs) and methods of fabricating Fin FETs that include an inner channel structure that includes a plurality of different material layers having sidewalls that extend from a semiconductor substrate and an outer channel layer on the sidewalls of the inner channel structure. The outer channel layer also has sidewalls. A gate dielectric layer may be provided on the sidewalls and an upper surface of the outer channel layer and have a sidewall and an upper surface opposite the outer channel layer. A gate electrode may be provided on a portion of the sidewalls and upper surface of the gate dielectric layer. A source region and a drain region may be disposed on opposite sides of the gate electrode.

In additional embodiments of the present invention, the outer channel layer comprises a Si epitaxial layer. Furthermore, each of the plurality of different material layers may comprise an upper surface opposite and substantially parallel to the substrate and a sidewall surface that is substantially perpendicular to the substrate. The channel layer may be directly on the sidewall surfaces of the plurality of layers of different materials.

In further embodiments of the present invention, the inner channel structure comprises alternating layers of Si and SiGe. The alternating layers may comprise epitaxial layers. The alternating layers may comprise more than one layer of Si and more than one layer of SiGe. An outermost layer of the alternating layers may comprise a SiGe layer. Furthermore, a portion of the outer channel layer may be is disposed directly on the outermost layer of the alternating layers. The gate electrode may include a poly-silicon layer.

In additional embodiments of the present invention, a first dielectric layer is provided on the substrate. The inner channel structure extends through the first dielectric layer and the outer channel layer is disposed on a portion of the inner channel structure extending beyond the first dielectric layer. The inner channel structure may include a portion of the substrate and the portion of the inner channel structure provided by the substrate may extend beyond the first dielectric layer. Alternatively, the inner channel structure may include a portion of the substrate and the portion of the inner channel structure provided by the substrate does not extend beyond the first dielectric layer.

In still further embodiments of the present invention, the substrate comprises a Si substrate. The outer channel layer may include portions that are strained in a direction parallel to a gate width. The gate dielectric and the gate electrode may comprise a damascene structure. The outer channel layer may include strained and unstrained portions. The strained and unstrained portions may comprise sidewalls of the outer channel layer.

Some embodiments of the present invention provide a Fin FET and/or methods of fabricating a Fin FET that includes an inner channel structure on a semiconductor substrate and having sidewalls that extend from the substrate and an upper surface opposite the substrate, an outer channel layer on the sidewalls and upper surface of the inner channel structure and having sidewalls and an upper surface opposite the inner channel structure. At least a portion of the outer channel layer on the sidewalls of the inner channel structure is strained. A gate dielectric layer is provided on the sidewalls and upper surface of the outer channel layer and has sidewalls and an upper surface opposite the outer channel layer. A gate electrode is provided on a portion of the sidewalls and upper surface of the gate dielectric layer. A source region and a drain region are disposed on opposite sides of the gate electrode.

In further embodiments of the present invention, the outer channel layer comprises a Si epitaxial layer. The inner channel structure may include a plurality of layers of different materials. Each of the plurality of layers of different materials may comprise an upper surface opposite and substantially parallel to the substrate and a sidewall surface that is substantially perpendicular to the substrate. The outer channel layer may be directly on the sidewall surfaces of the plurality of layers of different materials. The inner channel structure may comprise alternating layers of Si and SiGe. The alternating layers may comprise epitaxial layers. The alternating layers may comprise more than one layer of Si and more than one layer of SiGe. An outermost layer of the alternating layers may comprise a SiGe layer. A portion of the channel layer may be disposed directly on the outermost layer of the alternating layers. The gate electrode may comprise a poly-silicon layer.

In additional embodiments of the present invention, a first dielectric layer is provided on the substrate. The inner channel structure extends through the first dielectric layer and the outer channel layer is disposed on a portion of the inner channel structure extending beyond the first dielectric layer. The inner channel structure may include a portion of the substrate and the portion of the inner channel structure provided by the substrate extends beyond the first dielectric layer. Alternatively, the inner channel structure includes a portion of the substrate and the portion of the inner channel structure provided by the substrate does not extend beyond the first dielectric layer.

In further embodiments of the present invention, the substrate comprises a Si substrate. The outer channel layer may include portions that are strained in a direction parallel to a gate width. The gate dielectric and the gate electrode may comprise a damascene structure. The outer channel layer may include strained and unstrained portions. The strained and unstrained portions may comprise sidewalls of the outer channel layer.

### BRIEF DESCRIPTION OF THE DRAWINGS

FIG. 1A is a cross-sectional view illustrating a conventional planar FET.

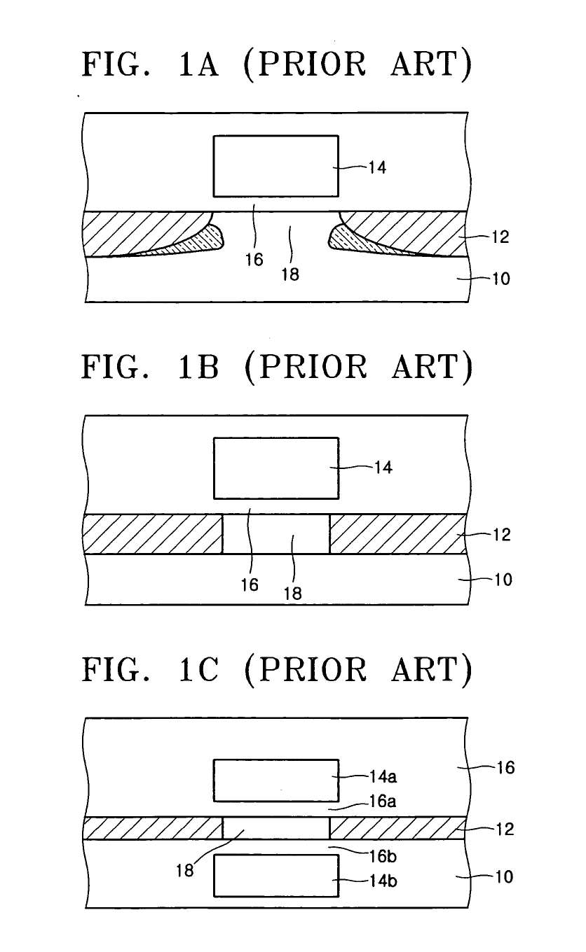

FIG. 1B is a cross-sectional view illustrating a conventional ultra-thin body transistor.

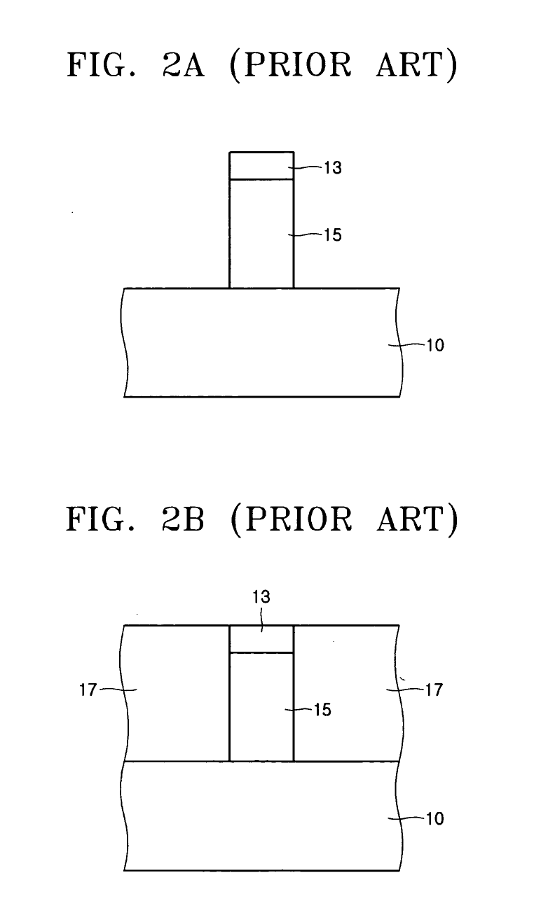

FIG. 1C is a cross-sectional view illustrating a conventional double-gate FET.

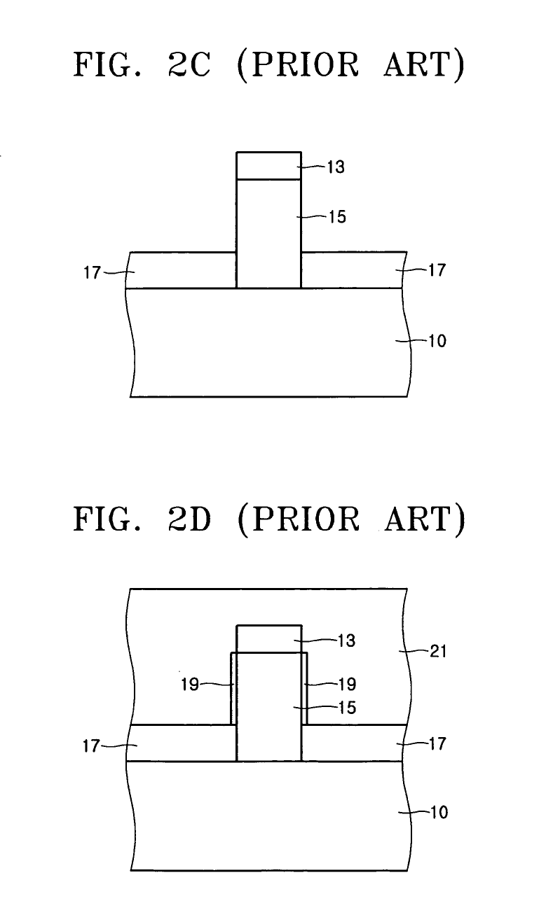

FIGS. 2A to 2D are cross-sectional views of a semiconductor substrate illustrating conventional methods of forming a conventional double-gate FinFET.

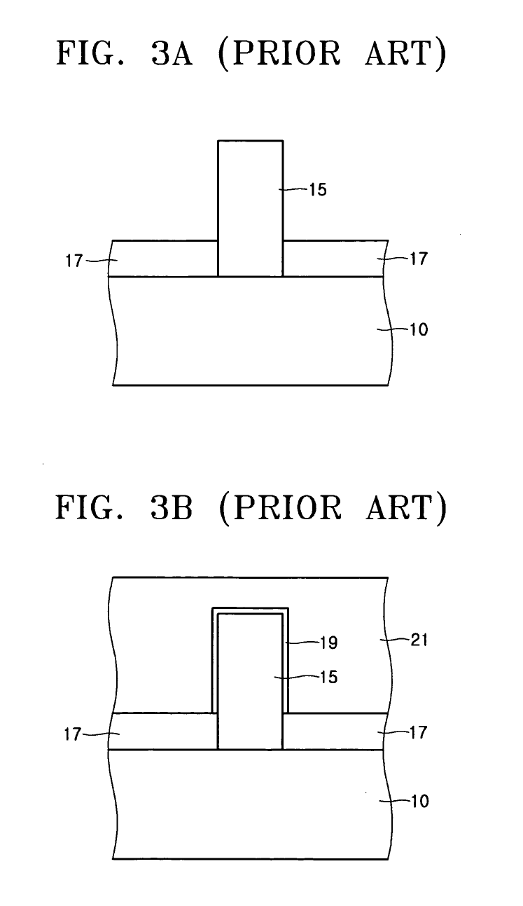

FIGS. 3A to 3B are cross-sectional views of a semiconductor substrate illustrating conventional methods of forming a conventional triple-gate FinFET.

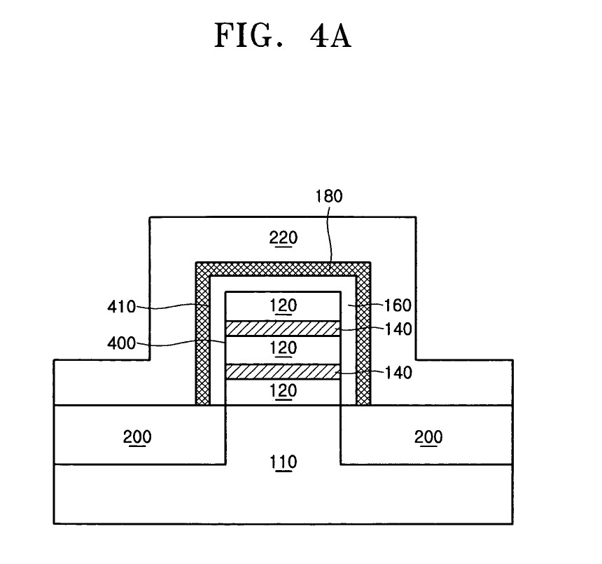

FIG. 4A is a cross-sectional view of a Fin FET according to some embodiments of the present invention.

FIG. 4B is an isometric pictorial view of a channel and gate region of a Fin FET according to some embodiments of the present invention.

FIG. 4C is a plan view of a Fin FET according to some embodiments of the present invention.

FIGS. 5A and 5B are schematic illustrations of lattice structures in a portion of a fin of a Fin FET according to some embodiments of the present invention.

FIGS. 6A through 6E are cross-sectional views illustrating methods of fabricating a Fin FET according to some embodiments of the present invention.

FIG. 7 is a cross-sectional view of a Fin FET according to further embodiments of the present invention.

### DETAILED DESCRIPTION OF EMBODIMENTS OF THE INVENTION

The present invention will be described more fully hereinafter with reference to the accompanying drawings, in which exemplary embodiments of the invention are shown. However, this invention should not be construed as limited to the embodiments set forth herein. Rather, these embodiments are provided so that this disclosure will be thorough and complete, and will fully convey the scope of the invention to those skilled in the art. In the drawings, the thickness of layers and regions are exaggerated for clarity. Like numbers refer to like elements throughout.

It will be understood that when an element such as a layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

It will also be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present invention.

Furthermore, relative terms, such as “lower” or “bottom” and “upper” or “top,” may be used herein to describe one element's relationship to another elements as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower”, can therefore, encompasses both an orientation of “lower” and “upper,” depending of the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

The terminology used in the description of the invention herein is for the purpose of describing particular embodiments only and is not intended to be limiting of the invention. As used in the description of the invention and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the invention.

Unless otherwise defined, all terms used in disclosing embodiments of the invention, including technical and scientific terms, have the same meaning as commonly understood by one of ordinary skill in the art to which this invention belongs, and are not necessarily limited to the specific definitions known at the time of the present invention being described. Accordingly, these terms can include equivalent terms that are created after such time. All publications, patent applications, patents, and other references mentioned herein are incorporated by reference in their entirety.

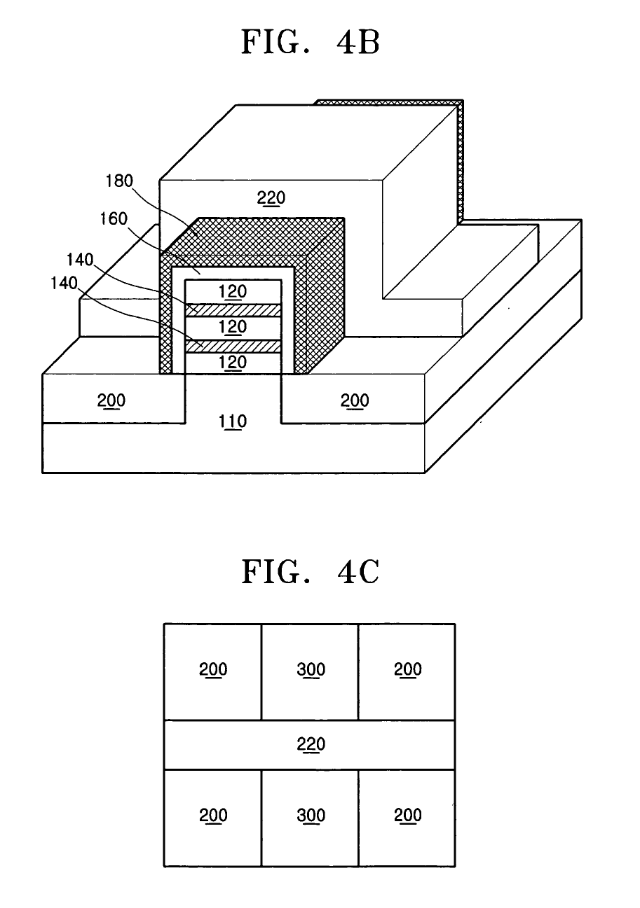

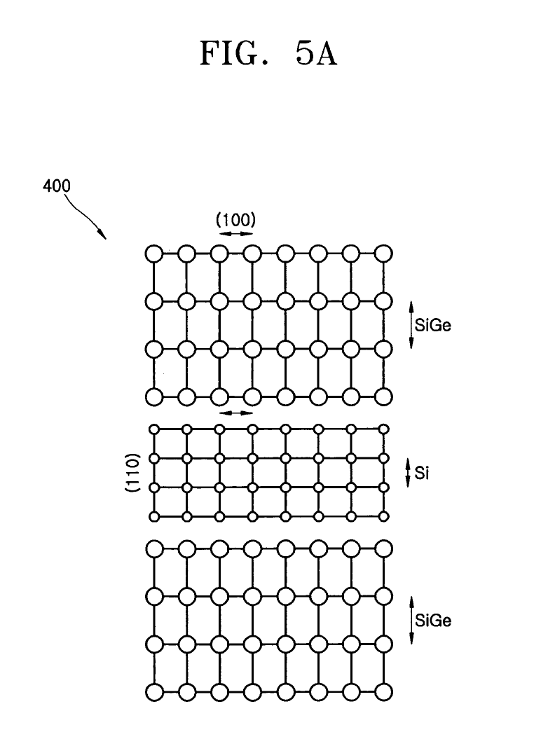

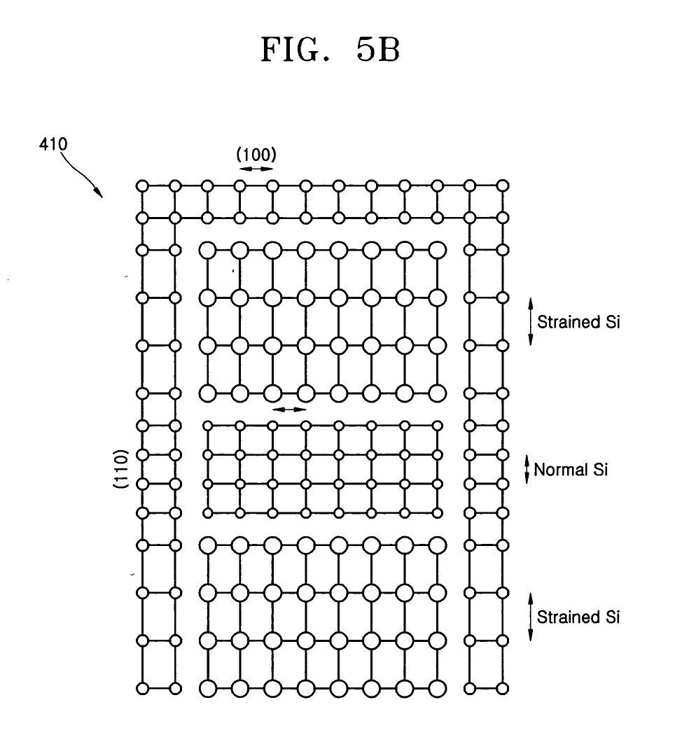

Some embodiments of the present invention will now be described with reference to FIGS. 4A through 7 that illustrate fin FET structures and methods of fabricating fin FETs having a channel layer with at least a portion of the channel layer being strained. However, the present invention should not be construed as limited to fin FET structures but may be used in other structures where a channel is formed on a sidewall of an underlying structure. Thus, for example, a strained channel may be provided in a recessed channel array transistor or a gate all around transistor in addition to the fin FET structures described herein. Accordingly, embodiments of the present invention may be used in FET structures where having a channel layer on sidewalls of a structure where at least a portion of a channel layer of the FET is strained in a direction that the sidewalls of the structure extend from a semiconductor substrate.

FIG. 4A illustrates a cross-sectional view of a portion of fin FETs according to some embodiments of the present invention. FIG. 4B is an isometric pictorial of a gate and channel region of the fin FETs of FIG. 4A. As seen in FIGS. 4A and 4B, a substrate 110 has an inner fin structure 400 that includes layers that are lattice matched and lattice mismatched to an outer fin structure 410 that provides a channel layer such that at least a portion of the outer fin structure 410 is strained in a direction perpendicular to the direction of current flow in the outer fin structure 410 (e.g., in the vertical direction illustrated in FIGS. 4A and 4B). As discussed below, as used herein layers may be lattice matched if a difference in the lattice constants of the two layers is insufficient to induce sufficient strain to enhance carrier mobility and lattice mismatched if the difference in the lattice constants of the two layers is sufficient to induce sufficient strain to enhance carrier mobility. In particular embodiments of the present invention, the substrate 110 may be a Si substrate and/or a silicon on insulator (SOI) substrate. Furthermore, the inner fin structure 400 may include SiGe layers 120 and Si layers 140, each of which may be epitaxial layers. Furthermore, the outer fin structure 410 may be a Si layer 160 that may be formed by selective epitaxial growth on the sidewall(s) and, in some embodiments, directly on the sidewall(s) of the inner fin structure 400 such that the Si layer 160 is formed directly on the SiGe layers 120 and the Si layers 140. In some embodiments, an outermost layer of the inner fin structure 400 is a SiGe layer 120.

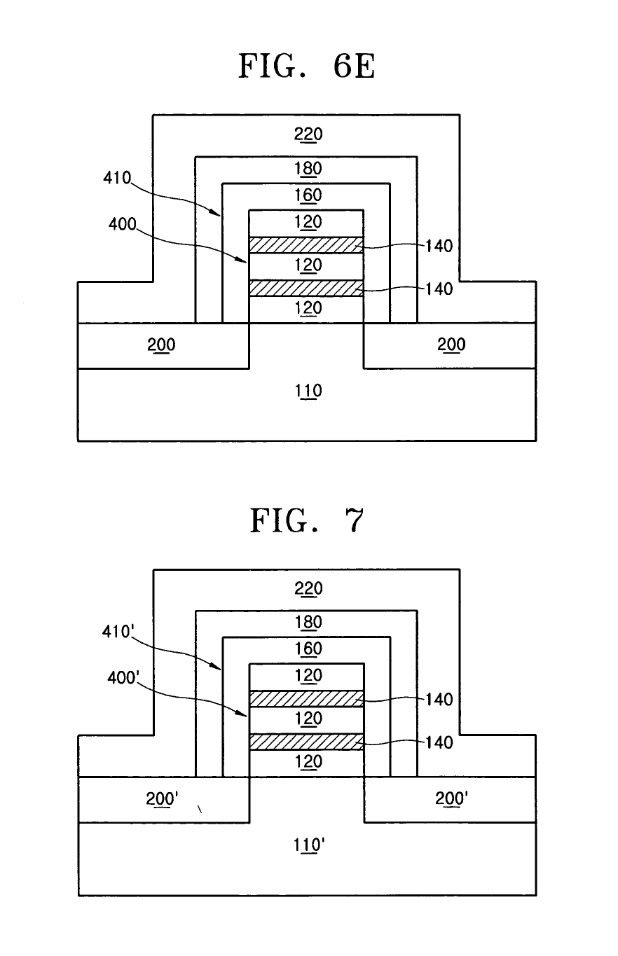

In particular embodiments of the present invention, a gate dielectric layer 180 is provided on the outer fin structure 410 and a gate electrode 220 is provided on the gate dielectric layer 180. In some embodiments of the present invention, the gate electrode 180 may be provided by a poly-silicon layer. Also illustrated in FIGS. 4A and 4B is a first dielectric layer 200 where a portion of the inner fin structure 400 extends through the first dielectric layer 200. The gate dielectric layer 180 may be an suitable gate dielectric layer or layers that may be suitable for use in a fin FET structure, including for example, an oxide, such as silicon dioxide. Likewise, the first dielectric layer 200 may be any suitable dielectric material, including for example, silicon dioxide. In the embodiments illustrated in FIGS. 4A and 4B, the portion of the inner fin structure 400 provided by the substrate 110 does not extend substantially beyond the first dielectric layer 200. However, in alternative embodiments, as illustrated in FIG. 7, a substrate 1101 and first dielectric layer 200′ may be provided where the portion of the inner fin structure 400′ provided by the substrate 110′ extends beyond the first dielectric layer 200′ and the outer fin structure 410′ is provided on a portion of the substrate 110′ protruding from the first dielectric layer 200′.

FIG. 4C illustrates source and drain regions 300 (not shown in FIGS. 4A, 4B and 7) that may also be provided on opposite sides of the gate electrode 220. The source and drain regions 300 maybe more heavily doped than the channel region of the inner fin structure 400 or the outer fin structure 410. The particular dopants utilized to dope the source and drain regions 300 depends on whether an NMOS or pMOS device is to be provided. In some embodiments, the source and drain regions 300 may be provided by the alternating layers of SiGe 120 and Si 140. The source and drain regions 300 may also be provided by the Si epitaxial layer 160. The source and drain regions 300 could also be provided by regions of Si or SiGe. The SiGe provided in the source and drain regions 300 may be doped more heavily than if only Si is provided in the source and drain regions. Furthermore, the source and drain regions 300 may be defined by counterdoping regions through ion implantation to define the source and drain regions.

In some embodiments of the present invention, the Si layers 140 and SiGe layers 120 are provided as epitaxial layers. The SiGe layers 120 may include about 30% Ge which may provide a 1.2% difference in the lattice constant between the SiG layers 120 and the Si epitaxial layer 160. The SiGe layers 120 may be as thick as possible but not so thick as to cause significant reduction in the quality of the SiGe layers 120, for example, by dislocation defects in the SiGe layers. The specific thickness of the SiGe layers 120 may depend on the amount of Ge in the layers, however, in some embodiments, for SiGe layers with about 30% Ge, a thickness of up to about 20 nm may be provided. In some embodiments, the Si layers 140 have a thickness of about 5 nm and the SiGe layers 120 have a thickness of about 20 nm. The number of layers of Si 140 and SiGe 120 may depend on the overall height of the inner fin structure 400 and the thicknesses of the individual layers. However, in some embodiments, more than one layer of Si and more than one layer of SiGe may be provided.

In particular embodiments of the present invention, the Si layers 140 have a thickness of less than about 30 Å and the SiGe layers have a thickness of less than about 50 Å. In some embodiments of the present invention, the overall height of the inner fin structure 400 is from about 100 nm to about 150 nm. Furthermore, an outermost layer of the alternating layers may be a SiGe layer 120 as illustrated in FIG. 4A.

The outer fin structure 410 may be provided by a Si epitaxial layer 160 formed on the inner fin structure 400. The Si epitaxial layer 160 may have a thickness of at least the anticipated channel depth of the device. However, in some embodiments, the Si epitaxial layer 160 may have a thickness of less than the expected depth of the channel of the device such that, in operation, the channel extends into the inner fin structure 400. The Si epitaxial layer 160 may be grown to a thickness of from about 20 Å to about 100 Å before formation of the gate oxide 180, however, other thicknesses may be used. The gate oxide 180 may be formed by thermal oxidation and may consume a portion of the Si epitaxial layer 160. Approximately 45% of the Si epitaxial layer 160 may be consumed during the thermal oxidation to provide the gate oxide 180. After formation of the gate oxide 180 at least about 10 Å of the Si epitaxial layer 160 may remain. The thickness of the Si epitaxial layer 160 as grown may differ if other techniques for formation of the gate oxide 180, such as by deposition, are used.

Thus, as illustrated in FIGS. 4A and 4B, an inner channel structure is provided by the inner fin structure 400 and includes a plurality of different material layers and has sidewalls that extend from the semiconductor substrate 110. The plurality of different material layers have an upper surface opposite and substantially parallel to the substrate 110 and a sidewall surface that is substantially perpendicular to the substrate 110. The plurality of different material layers may be provided as a stack of multiple layers of different semiconductor materials. An outer channel layer is provided by the outer fin structure 410 and is on the sidewalls of the inner channel structure. The outer channel layer also has sidewalls and may be directly on sidewalls of the plurality of different material layers of the inner channel structure. At least a portion of the outer channel layer on the sidewalls of the inner channel structure is strained. The gate dielectric layer 180 is provided on the sidewalls and an upper surface of the outer channel layer and has a sidewall and upper surface opposite the outer channel layer. The gate electrode 220 is provided on a portion of the sidewalls and upper surface of the gate dielectric layer 180.

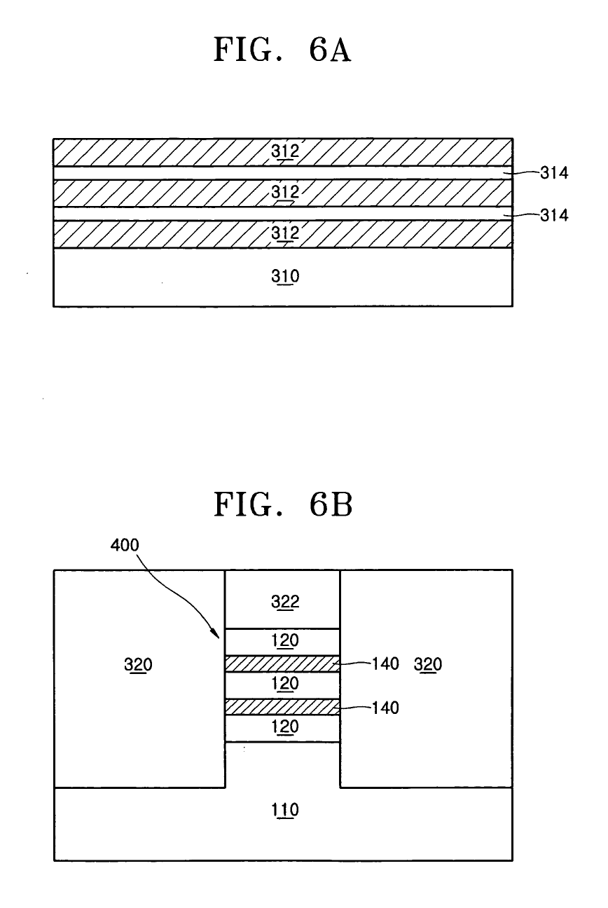

FIGS. 5A and 5B schematically illustrate lattice structures of the inner fin structure 400 and the outer fin structure 410 that provides a channel layer according to some embodiments of the present invention. As seen in FIGS. 5A and 5B, the inner fin structure 400 includes SiGe layers that are substantially lattice matched with the Si layers in the (100) plane and mismatched with the Si layer of the outer fin structure in the (110) plane. Thus, the outer fin structure 410 that provides the channel layer is strained where the outer fin structure 410 is formed on the SiGe layers of the inner fin structure 400 and unstrained where the outer fin structure 410 is formed on the Si layers of the inner fin structure 400. As used herein, the terms lattice mismatch and lattice match refers to differences in the lattice constants of the two materials. Furthermore, differences in the lattice constant are considered substantial if the differences result in inducing a strain in one of the layers that is sufficient to enhance carrier mobility, at least in part as a result of the strain induced in the layer.

As seen in FIG. 5B, the outer fin structure that provides the channel layer may include strained and unstrained portions as a result of the lattice mismatch between the inner fin structure and the outer fin structure. Because the strain is in the vertical direction in the diagram of FIG. 5B and current flow is into or out of the page in a fin FET configuration, the direction of strain is parallel to the width of the gate/channel. Because the SiGe layers have a larger lattice constant than the Si layers, the strain in the Si layer on the SiGe layers will be tensile. According to Ge et al., “Process-Strained Si (PSS) CMOS Technology Featuring 3D Strain Engineering,” Electron Devices Meeting, 2003. IEDM '03 Technical Digest. IEEE International, pp. 3.7.1-3.7.4, tensile strain that is perpendicular to the flow of current and the gate width may improve performance of both nMOS and pMOS devices. Accordingly, fin structures according to embodiments of the present invention may be suitable for use in both nMOS and pMOS devices.

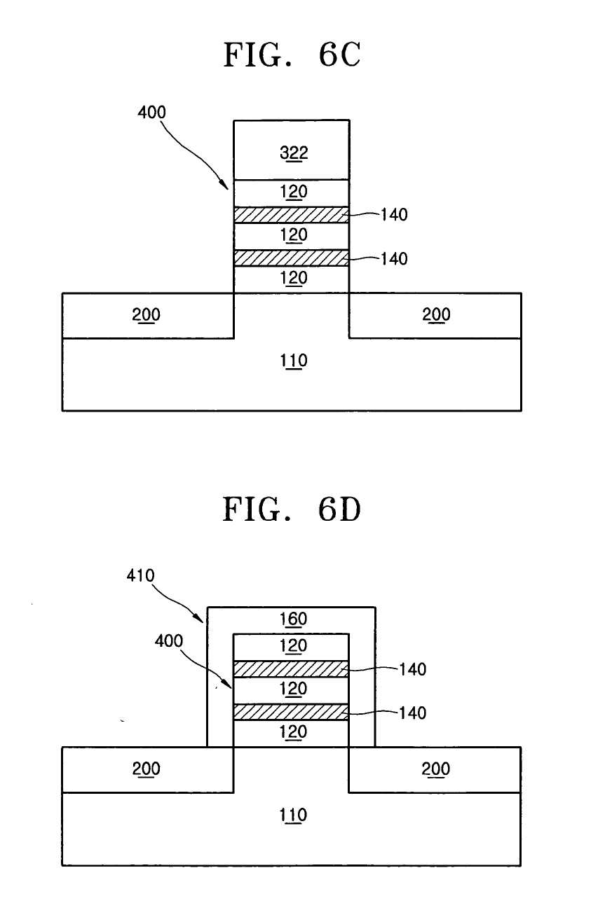

FIGS. 6A through 6E illustrate methods of fabricating FETs having strained channel layers according to some embodiments of the present invention. As seen in FIG. 6A, alternating layers of SiGe 312 and Si 314 are formed on a Si substrate 310. The alternating layers of SiGe 312 and Si 314 may be formed by epitaxial growth and may be formed having dimensions as described above. Optionally, if a counterdoping implant is performed on the resulting structure of FIG. 6A, a buffer layer (not shown), such as an oxide layer, may be provided between the Si substrate 310 and the alternating layers of SiGe 312 and Si 314. Alternatively, blanket ion implantation may be performed on the resulting structure of FIG. 6A, thus making counterdoping unnecessary.

As illustrated in FIG. 6B, the inner fin structure 400 of FIGS. 4A and 4B may be formed by etching the structure of FIG. 6A through the alternating layers of SiGe 312 and Si 314 and into the substrate 310 to provide the substrate 110, SiGe layers 120 and Si layers 140 that form the inner fin structure. A SiN layer 322 may be provided on the inner fin structure and may be used as an etch mask. Furthermore, an oxide layer 320, such as SiO₂, may be formed on the substrate 110 to surround the fin structure. In some embodiments of the present invention, after formation of the fin structure, an oxide layer is formed on the structure and a trench etched in the oxide layer corresponding to the fin structure to provide the oxide layer 320. The trench is then filled by a SiN layer and a chemical mechanical polishing procedure is carried out to provide the SiN layer 322 in the trench. As discussed above, the SiN layer 322 may act as a mask during a subsequent etch back of the oxide layer 320.

FIG. 6C illustrates the etch back of the oxide layer 320 to provide the oxide layer 200. As seen in FIG. 6C, the oxide layer 320 may be recessed to the substrate 110 or, in some embodiments as illustrated in FIG. 7, may be recess to beyond the portion of the substrate 110 that forms a portion of the fin structure. Optionally, the fin structure may be trimmed or thinned such that the width of the fin structure is reduced.

FIG. 6D illustrates the formation of the Si layer 160 on the inner fin structure 400. The Si layer 160 that provides the outer fin structure 410 may be formed by selective epitaxial growth of a Si layer on the SiGe layers 120 and the Si layers 140 such that the Si layer 160 is formed on the sidewalls of the inner fin structure 400. The Si layer 160 could also be formed by solid phase epitaxy by forming an amorphous silicon layer on the inner fin structure 400 and then annealing the amorphous layer to convert the layer to crystalline.

FIG. 6E illustrates the formation of the gate oxide 180 and the gate electrode 220. As discussed above, the gate oxide 180 may be formed by thermal oxidation of the Si layer 160. The gate electrode 220 may be formed and patterned using conventional gate patterning techniques. Optionally, after formation and patterning of the gate electrode 220, the source and drain regions may be enlarged by selective epitaxial growth in the source and drain regions.

In some embodiments of the present invention, the gate structure is formed by a damascene process to provide a damascene gate structure. In such embodiments, the gate may be formed in a recess around the fin structure and a blanket deposition of gate material may be carried out followed by a CMP or other planarization to remove the gate material that is not in the recess. In such a case, there may be no need to expand the source and drain regions.

In the drawings and specification, there have been disclosed typical embodiments of the invention and, although specific terms are employed, they are used in a generic and descriptive sense only and not for purposes of limitation, the scope of the invention being set forth in the following claims.

1. A field effect transistor (FET) comprising a channel layer on sidewalls of a structure on a semiconductor substrate and having at least a portion of the channel layer strained in a direction that the sidewalls of the structure extend from the semiconductor substrate.

2. The FET of claim 1, wherein the transistor comprises a FinFET, wherein the structure comprises a fin structure and wherein the sidewalls comprise sidewalls of the fin structure.

3. The FinFET of claim 2, wherein the channel layer comprises a Si epitaxial layer.

4. The FinFET of claim 3, wherein the channel layer has a thickness of less than about 100 Å.

5. The FinFET of claim 2, wherein the fin structure comprises a plurality of layers of different materials.

6. The FinFET of claim 5, wherein each of the plurality of layers of different materials comprises an upper surface opposite and substantially parallel to the substrate and a sidewall surface that is substantially perpendicular to the substrate, and
wherein the channel layer is directly on the sidewall surfaces of the plurality of layers of different materials.

7. The FinFET of claim 2, wherein the fin structure comprises alternating layers of Si and SiGe.

8. The FinFET of claim 7, wherein the alternating layers comprise epitaxial layers.

9. The FinFET of claim 7, wherein the Si layers of the alternating layers have a thickness of less than about 30 Å.

10. The FinFET of claim 7, wherein the SiGe layers of the alternating layers have a thickness of less than about 50 Å.

11. The FinFET of claim 7, wherein the alternating layers comprise more than one layer of Si and more than one layer of SiGe.

12. The FinFET of claim 7, wherein an outermost layer of the alternating layers comprises a SiGe layer.

13. The FinFET of claim 12, wherein a portion of the channel layer is disposed directly on the outermost layer of the alternating layers.

14. The FinFET of claim 2, further comprising:
a gate dielectric on the channel layer;
a gate electrode on a portion of the gate dielectric; and
source and drain regions on opposite sides of the gate electrode.

15. The FinFET of claim 14, wherein the channel layer comprises a Si epitaxial layer.

16. The FinFET of claim 15, wherein the source and drain regions comprise the Si epitaxial layer.

17. The FinFET of claim 14, wherein the fin structure and the source and drain regions comprise a plurality of layers of different materials.

18. The FinFET of claim 14, wherein the fin structure and the source and drain regions comprise alternating layers of Si and SiGe.

19. The FinFET of claim 18, wherein the alternating layers comprise epitaxial layers.

20. The FinFET of claim 14, wherein the gate electrode comprises a poly-silicon layer.

21. The FinFET of claim 2, further comprising a first dielectric layer on the substrate, wherein the fin structure extends through the first dielectric layer and the channel layer is disposed on a portion of the fin structure extending beyond the first dielectric layer.

22. The FinFET of claim 21, wherein the fin structure includes a portion of the substrate and wherein the portion of the fin structure provided by the substrate extends beyond the first dielectric layer.

23. The FinFET of claim 21, wherein the fin structure includes a portion of the substrate and wherein the portion of the fin structure provided by the substrate does not extend beyond the first dielectric layer.

24. The FinFET of claim 2, wherein the substrate comprises a Si substrate.

25. The FinFET of claim 14, wherein the channel layer includes portions that are strained in a direction parallel to a gate width.

26. The FinFET of claim 14, wherein the gate dielectric and the gate electrode comprise a damascene structure.

27. The FinFET of claim 2, wherein the channel layer includes strained and unstrained portions.

28. The FinFET of claim 27, wherein the strained and unstrained portions comprise sidewalls of the channel layer.

29. A Fin field effect transistor (FET), comprising:
an inner channel structure comprising a plurality of different material layers having sidewalls that extend from a semiconductor substrate; and
an outer channel layer on the sidewalls of the inner channel structure, the outer channel layer having sidewalls.

30. The FinFET of claim 29, further comprising:
a gate dielectric layer on the sidewalls and an upper surface of the outer channel layer and having a sidewall and an upper surface opposite the outer channel layer;
a gate electrode on a portion of the sidewalls and upper surface of the gate dielectric layer; and
a source region and a drain region disposed on opposite sides of the gate electrode.

31. The FinFET of claim 30, wherein the outer channel layer comprises a Si epitaxial layer.

32. The FinFET of claim 30, wherein each of the plurality of different material layers comprises an upper surface opposite and substantially parallel to the substrate and a sidewall surface that is substantially perpendicular to the substrate, and
wherein the channel layer is directly on the sidewall surfaces of the plurality of layers of different materials.

33. The FinFET of claim 30, wherein the inner channel structure comprises alternating layers of Si and SiGe.

34. The FinFET of claim 33, wherein the alternating layers comprise epitaxial layers.

35. The FinFET of claim 33, wherein the alternating layers comprise more than one layer of Si and more than one layer of SiGe.

36. The FinFET of claim 33, wherein an outermost layer of the alternating layers comprises a SiGe layer.

37. The FinFET of claim 36, wherein a portion of the outer channel layer is disposed directly on the outermost layer of the alternating layers.

38. The FinFET of claim 30, wherein the gate electrode comprises a poly-silicon layer.

39. The FinFET of claim 30, further comprising a first dielectric layer on the substrate, wherein the inner channel structure extends through the first dielectric layer and the outer channel layer is disposed on a portion of the inner channel structure extending beyond the first dielectric layer.

40. The FinFET of claim 39, wherein the inner channel structure includes a portion of the substrate and wherein the portion of the inner channel structure provided by the substrate extends beyond the first dielectric layer.

41. The FinFET of claim 39, wherein the inner channel structure includes a portion of the substrate and wherein the portion of the inner channel structure provided by the substrate does not extend beyond the first dielectric layer.

42. The FinFET of claim 30, wherein the substrate comprises a Si substrate.

43. The FinFET of claim 30, wherein the outer channel layer includes portions that are strained in a direction parallel to a gate width.

44. The FinFET of claim 30, wherein the gate dielectric and the gate electrode comprise a damascene structure.

45. The FinFET of claim 30, wherein the outer channel layer includes strained and unstrained portions.

46. The FinFET of claim 45, wherein the strained and unstrained portions comprise sidewalls of the outer channel layer.

47. A Fin field effect transistor (FET), comprising:
an inner channel structure on a semiconductor substrate and having sidewalls that extend from the substrate and an upper surface opposite the substrate;
an outer channel layer on the sidewalls and upper surface of the inner channel structure and having sidewalls and an upper surface opposite the inner channel structure and wherein at least a portion of the outer channel layer on the sidewalls of the inner channel structure is strained;
a gate dielectric layer on the sidewalls and upper surface of the outer channel layer and having sidewalls and an upper surface opposite the outer channel layer;
a gate electrode on a portion of the sidewalls and upper surface of the gate dielectric layer; and
a source region and a drain region disposed on opposite sides of the gate electrode.

48. The FinFET of claim 47, wherein the outer channel layer comprises a Si epitaxial layer.

49. The FinFET of claim 47, wherein the inner channel structure comprises a plurality of layers of different materials.

50. The FinFET of claim 49, wherein each of the plurality of layers of different materials comprises an upper surface opposite and substantially parallel to the substrate and a sidewall surface that is substantially perpendicular to the substrate, and
wherein the outer channel layer is directly on the sidewall surfaces of the plurality of layers of different materials.

51. The FinFET of claim 47, wherein the inner channel structure comprises alternating layers of Si and SiGe.

52. The FinFET of claim 51, wherein the alternating layers comprise epitaxial layers.

53. The FinFET of claim 51, wherein the alternating layers comprise more than one layer of Si and more than one layer of SiGe.

54. The FinFET of claim 51, wherein an outermost layer of the alternating layers comprises a SiGe layer.

55. The FinFET of claim 54, wherein a portion of the channel layer is disposed directly on the outermost layer of the alternating layers.

56. The FinFET of claim 47, wherein the gate electrode comprises a poly-silicon layer.

57. The FinFET of claim 47, further comprising a first dielectric layer on the substrate, wherein the inner channel structure extends through the first dielectric layer and the outer channel layer is disposed on a portion of the inner channel structure extending beyond the first dielectric layer.

58. The FinFET of claim 57, wherein the inner channel structure includes a portion of the substrate and wherein the portion of the inner channel structure provided by the substrate extends beyond the first dielectric layer.

59. The FinFET of claim 57, wherein the inner channel structure includes a portion of the substrate and wherein the portion of the inner channel structure provided by the substrate does not extend beyond the first dielectric layer.

60. The FinFET of claim 47, wherein the substrate comprises a Si substrate.

61. The FinFET of claim 47, wherein the outer channel layer includes portions that are strained in a direction parallel to a gate width.

62. The FinFET of claim 47, wherein the gate dielectric and the gate electrode comprise a damascene structure.

63. The FinFET of claim 47, wherein the outer channel layer includes strained and unstrained portions.

64. The FinFET of claim 63, wherein the strained and unstrained portions comprise sidewalls of the outer channel layer.

65. A method of fabricating a field effect transistor (FET) comprising:
forming a channel layer on sidewalls of a structure on a semiconductor substrate, wherein the channel layer has at least a strained portion in a direction that the sidewalls of the structure extend from the semiconductor substrate.

66-121. (canceled)
